(19) United States
(12) Patent Application Publication
(10) Pub. No.: US 2024/0204034 A1
(43) Pub. Date: Jun. 20, 2024

(54) METHOD OF MANUFACTURING DETECTION PANEL

(71) Applicant: InnoCare Optoelectronics Corporation, Tainan City (TW)

(72) Inventors: Wen-Chien Lin, Tainan City (TW); Chih-Hao Wu, Tainan City (TW)

(73) Assignee: InnoCare Optoelectronics Corporation, Tainan City (TW)

(21) Appl. No.: 18/503,192

(22) Filed: Nov. 7, 2023

Related U.S. Application Data
(60) Provisional application No. 63/433,762, filed on Dec. 20, 2022.

(30) Foreign Application Priority Data
Jun. 19, 2023 (TW) 112122950

(51) Int. Cl. H01L 27/146

(52) U.S. Cl. CPC H01L 27/14663; H01L 27/14683

(57) ABSTRACT

Disclosed is a method for manufacturing a detection panel, which includes the following steps. A first flexible board is provided, and the first flexible board has a circuit layer. A second flexible board is provided, the first flexible board is fixed on the second flexible board, and the first flexible board is disposed between the circuit layer and the second flexible board. A carrier board is provided, the carrier board is fixed on the second flexible board, and the second flexible board is disposed between the carrier board and the first flexible board. A scintillator is formed on the circuit layer. The carrier board is detached from the second flexible board. The first flexible board and the second flexible board are cut to form the detection panel.

### CROSS-REFERENCE TO RELATED APPLICATION

This application claims the priority benefit of U.S. provisional application Ser. No. 63/433,762, filed on Dec. 20, 2022, and Taiwan application serial no. 112122950, filed on Jun. 19, 2023. The entirety of each of the above-mentioned patent applications is hereby incorporated by reference herein and made a part of this specification.

### BACKGROUND

### Field of the Disclosure

The disclosure relates to a method of manufacturing an electronic device, and in particular to a method of manufacturing a detection panel.

### Description of Related Art

In currently available methods of manufacturing detection panel, a scintillator may be directly or indirectly grown on the circuit layer. In an example of indirectly growing the scintillator, the scintillator is first formed on the substrate, and then the substrate carrying the scintillator is disposed on the circuit layer by adhering (such as optical adhesive). In the example of directly growing the scintillator, the scintillator is directly formed on the glass substrate carrying the circuit layer by evaporation.

In the case that the scintillator is indirectly formed on the circuit layer through the above method, there will be relatively a large number of layers between the scintillator and the circuit layer. When the scintillator converts the X-rays it absorbs into visible light, these layers may reflect and/or absorb part of visible light. Furthermore, during the above adhering process, air bubbles are likely to be generated between the scintillator and the circuit layer. The problems described above will reduce the quantum efficiency and/or resolution of the detection panel.

When the scintillator is directly formed on the circuit layer through the above method, the quality of the detection panel is relatively poor because the glass substrate is heavy and unable to withstand the impact of a fall.

### SUMMARY OF THE DISCLOSURE

The disclosure provides a method for manufacturing a detection panel, which may improve the quantum efficiency and resolution of the detection panel, and enable the detection panel to have a relatively good quality.

Some embodiments of the present disclosure provide a method for manufacturing a detection panel, which includes the following steps. A first flexible board is provided, and the first flexible board has a circuit layer. A second flexible board is provided, and the first flexible board is fixed on the second flexible board, and the first flexible board is disposed between the circuit layer and the second flexible board. A carrier board is provided, the carrier board is fixed on the second flexible board, and the second flexible board is disposed between the carrier board and the first flexible board. A scintillator is formed on the circuit layer. The carrier board is detached from the second flexible board. The first flexible board and the second flexible board are cut to form the detection panel.

Some other embodiments of the present disclosure provide a method for manufacturing a detection panel, which includes the following steps. A first flexible board is provided, and the first flexible board has a circuit layer. A second flexible board is provided, and the first flexible board is fixed on the second flexible board, the first flexible board is disposed between the circuit layer and the second flexible board. A carrier board is provided, the carrier board is fixed on the second flexible board, and the second flexible board is disposed between the carrier board and the first flexible board. A scintillator is formed on the circuit layer. The first flexible board and the second flexible board are cut and detached from the carrier board.

Based on the above, in the method for manufacturing the detection panel according to an embodiment of the present disclosure, the scintillator is directly formed on the circuit layer, so the quantum efficiency and resolution of the detection panel may be improved. In addition, in the method for manufacturing the detection panel according to an embodiment of the present disclosure, the flexible board serves as the supporting layer of the detection panel, so the quality of the detection panel may be improved.

### BRIEF DESCRIPTION OF THE DRAWINGS

FIG. 1 is a flowchart of a method for manufacturing a detection panel according to an embodiment of the present disclosure.

FIG. 2 is a schematic cross-sectional flow diagram of a method for manufacturing a detection panel according to an embodiment of the present disclosure.

FIG. 3 is a flowchart of a method for manufacturing a detection panel according to another embodiment of the disclosure.

FIG. 4 is a schematic cross-sectional flow diagram of a method of manufacturing a detection panel according to another embodiment of the present disclosure.

FIG. 5 is a schematic top view before cutting the first flexible board and the second flexible board in the method of manufacturing the detection panel according to an embodiment of the present disclosure.

### DESCRIPTION OF EMBODIMENTS

Reference will now be made in detail to the exemplary embodiments of the present disclosure, examples of which are illustrated in the accompanying drawings. Wherever possible, the same reference numbers are used in the drawings and descriptions to refer to the same or like parts.

The present disclosure can be understood by referring to the following detailed description and combined with the accompanying drawings. It should be noted that, for the purpose of easy comprehension and conciseness of drawings, several drawings in the present disclosure only depict a part of the electronic device. Also, certain elements in the drawings are not drawn to actual scale. In addition, the number and size of various components in the figure are only for illustration, and are not intended to limit the scope of the present disclosure.

Certain terms will be used throughout the specification and appended claims of this disclosure to refer to particular elements. Those skilled in the art should understand that electronic device manufacturers may refer to the same component by different names. The text does not intend to distinguish between those elements that have the same function but have different names. In the following description and claims, terms such as “comprising” and “including” are open-ended words, so they should be interpreted as meaning “including but not limited to . . . ”. Therefore, when the terms “comprising”, “comprising” and/or “having” are used in the description of the present disclosure, it specifies the existence of corresponding features, regions, steps, operations and/or components, but does not exclude the existence of one or more a corresponding feature, region, step, operation and/or component.

The directional terms mentioned herein, such as “upper”, “lower”, “front”, “rear”, “left”, “right”, etc., only refer to the directions of the accompanying drawings. Accordingly, the directional terms are used for illustration, not for limitation of the present disclosure. In the drawings, each figure illustrates the general characteristics of methods, structures and/or materials used in particular embodiments. However, these drawings should not be interpreted as defining or limiting the scope or nature encompassed by these embodiments. For example, the relative sizes, thicknesses and positions of layers, regions and/or structures may be reduced or exaggerated for clarity.

A corresponding component (e.g., layer or region) is located on/over “another component”, which can mean that the corresponding component is directly on another component, or it can mean that there are other components between the two. On the other hand, when a component is referred to as being “directly on” another component, then there is no component in between. In addition, when a component is referred to as “on another component”, the two have a vertical relationship in the top view direction, and the component can be above or below the other component, and this vertical relationship depends on the orientation of the device.

The terms “about”, “equal to”, “equivalent to” or “identical”, “substantially” or “generally” are normally interpreted as being within 20% of a given value or range, or as being within 10%, 5%, 3%, 2%, 1%, or 0.5% of a given value or range. In addition, the description that “the range is from the first value to the second value” and “the range is between the first value and the second value” mean that the range includes the first value, the second value and other values therebetween.

Ordinal numbers used in the specification and claims, such as “first”, “second”, etc., are used to modify elements, which neither implies nor means that the (or these) elements are preceded by any ordinal numbers, nor indicates the order of a certain element with another element, or the order of the manufacturing method. The use of these ordinal numbers is only used to clearly distinguish the element with a certain name from another element with the same name. Different terms may be adopted in claims and the specification, accordingly, the first component in the description may be referred to as the second component in the claim.

It should be noted that in the following embodiments, without departing from the spirit of the present disclosure, features in several different embodiments may be replaced, reorganized, and mixed to complete other embodiments. As long as the features of the various embodiments do not violate the spirit of the disclosure or conflict with each other, they can be mixed and matched freely.

The electrical connection or coupling described in this disclosure can refer to direct connection or indirect connection. In the case of direct connection, the terminals of the elements on the two circuits are directly connected or connected to each other with a conductor line segment. In the case of indirect connection, there are switches, diodes, capacitors, inductors, resistors, other suitable elements, or a combination of the above elements between the terminals of the elements on the two circuits, but not limited thereto.

In this disclosure, the thickness, length and width may be measured by optical microscope (OM), and the thickness may be obtained by measuring the cross-sectional image in the electron microscope, but the disclosure is not limited thereto. Additionally, any two values or directions used for comparison may have certain errors. If the first value is equal to the second value, it implies that there may be an error of about 10% between the first value and the second value. If the first direction is perpendicular to the second direction, the angle between the first direction and the second direction can be between 80 degrees and 100 degrees; if the first direction is parallel to the second direction, the angle between the first direction and the second direction may be between 0 degrees and 10 degrees.

In the present disclosure, the electronic device may include a detection device, a display device, an antenna device (e.g., liquid crystal antenna), a luminous touch device, a splicing device, devices with other suitable functions, or a combination of devices with the above functions, but not limited thereto. The electronic device may be a bendable or flexible electronic device, but not limited thereto. The electronic device may include, for example, liquid crystal, light-emitting diode (LED), photodiode, quantum dot (QD), fluorescence, phosphor, other suitable materials, or a combination thereof. An electronic device may include electronic components, and the electronic components may include passive components and active components, such as capacitors, resistors, inductors, diodes, transistors, and so on. The diodes may include light-emitting diodes or photodiodes. The light-emitting diode may include, for example, an organic light emitting diode (OLED), a mini light-emitting diode (mini LED), a micro light-emitting diode (micro LED) or a quantum dot light-emitting diode (quantum dot (QD), which may be QLED, QDLED, for example), or other suitable materials or any permutation or combination of the above materials, but not limited thereto. It should be noted that, the electronic device can be any permutation and combination mentioned above, but not limited thereto. In addition, the shape of the electronic device may be rectangular, circular, polygonal, with curved edges, or other suitable shapes. An electronic device may have peripheral systems such as a drive system, a control system, a light source system, a shelf system . . . to support a display device or a splicing device. It should be noted that the electronic device can be any permutation and combination of the aforementioned, but not limited thereto. An electronic device may include multiple components, at least two of which may be assembled to form a composite. In the following, the detection panel will be used as an electronic device to illustrate the present disclosure, but the present disclosure is not limited thereto.

Exemplary embodiments of the present disclosure are illustrated below, and the same reference numerals are used in the drawings and descriptions to denote the same or similar parts.

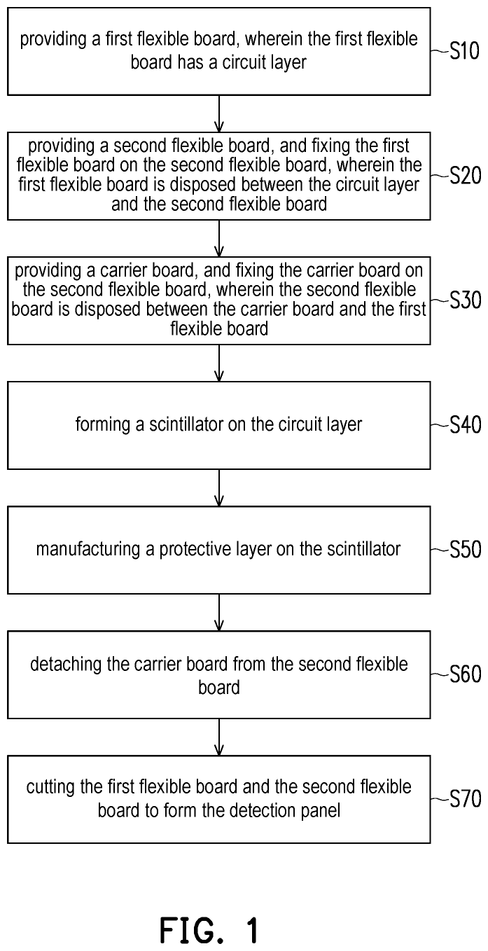

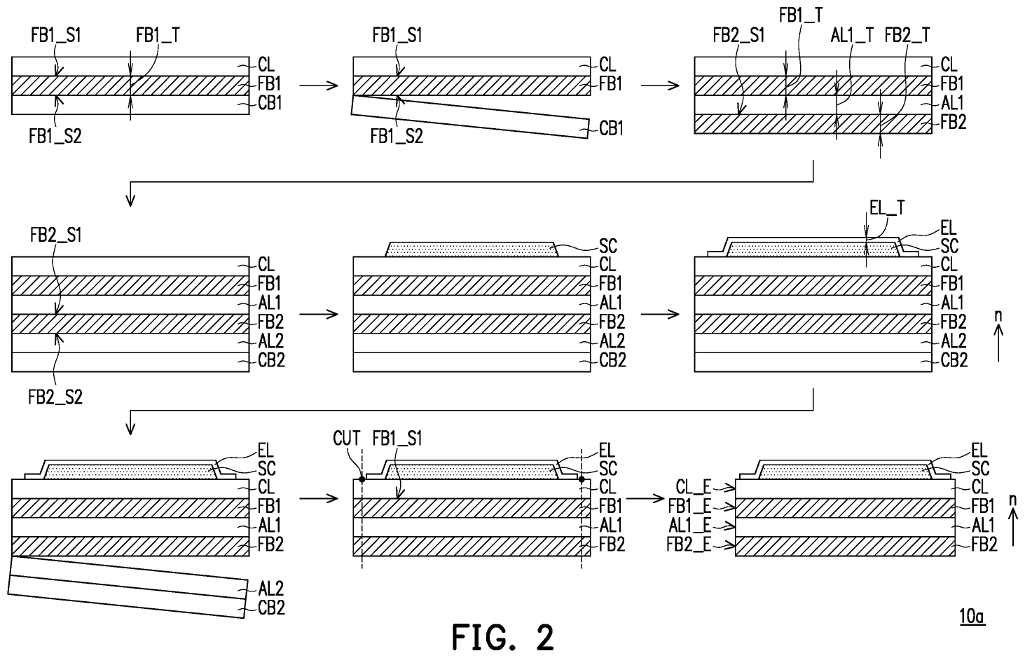

FIG. 1 is a flowchart of a method for manufacturing a detection panel according to an embodiment of the present disclosure. FIG. 2 is a schematic cross-sectional flow diagram of a method for manufacturing a detection panel according to an embodiment of the present disclosure.

Please refer to FIG. 1 and FIG. 2 at the same time. In step S10, a first flexible board FB1 is provided, and a circuit layer CL is provided on the first flexible board FB1.

The first flexible board FB1 may be, for example, used as a substrate for subsequently formed scintillator. In some embodiments, the thickness FB1_T of the first flexible board FB1 may be between 10 microns and 200 microns, but the disclosure is not limited thereto. The material of the first flexible board FB1 may for example include polyimide (PI), polyethylene terephthalate (PET), polyethylene naphthalate (PEN) or other suitable materials or combinations of the above materials, the present disclosure is not limited thereto.

The circuit layer CL is, for example, disposed on the first surface FB1_S1 of the first flexible board FB1. In some embodiments, the circuit layer CL may include switching elements (not shown), photoelectric elements (not shown), and multiple wires (not shown).

The switching element may, for example, include a gate (not shown), a source (not shown), a drain (not shown) and a semiconductor layer (not shown), but the disclosure is not limited thereto. The gate is, for example, disposed on the first flexible board FB1. The material of the gate may, for example, include molybdenum (Mo), titanium (Ti), tantalum (Ta), niobium (Nb), hafnium (Hf), nickel (Ni), chromium (Cr), cobalt (Co), zirconium (Zr), tungsten (W), aluminum (Al), copper (Cu), silver (Ag), other suitable metals or alloys or combinations of the above materials, the present disclosure is not limited thereto. For example, the semiconductor layer is disposed between the first flexible board FB1 and the gate, but the present disclosure is not limited thereto. In some embodiments, the semiconductor layer may at least partially overlap the gate, but the disclosure is not limited thereto. The material of the semiconductor layer may, for example, include oxide semiconductor, amorphous silicon semiconductor, polysilicon semiconductor, other suitable semiconductor materials or a combination of the above materials, and the present disclosure is not limited thereto. The source and the drain are, for example, disposed on the semiconductor layer and separated from each other. They may be in direct contact with and coupled to the semiconductor layer, but the disclosure is not limited thereto. In other embodiments, an insulating layer (not shown) may be provided between the semiconductor layer and the source and drain, the insulating layer has a through hole, and the source and drain may be coupled to the semiconductor layer through the through hole.

The photoelectric element may, for example, include a bottom electrode (not shown), a top electrode (not shown) and a photoelectric conversion layer (not shown), and the photoelectric element may be coupled to the switching element through the bottom electrode. In some embodiments, the photoelectric conversion layer in the photoelectric element may receive light and generate carriers (such as electrons and/or holes), and the carriers are stored in the photoelectric element when the switching element is not turned on. After the switching element is turned on, the carriers stored in the photoelectric element may be transmitted to the processing circuit (not shown) through the bottom electrode and the data line (reading line) among the multiple wires coupled with the switching element, for example, so as to realize the function of light detection. In addition, the top electrode is, for example, coupled to a voltage line among the plurality of wires. The material of the bottom electrode and the top electrode may include, for example, a transparent conductive material such as indium tin oxide (ITO), but the disclosure is not limited thereto. The material of the photoelectric conversion layer may include a doped semiconductor, an undoped semiconductor, or a combination thereof. For example, the photoelectric conversion layer may include a first layer, an intrinsic layer, and a second layer arranged in sequence, and materials of the first layer and the second layer include doped semiconductors, and materials of the intrinsic layer include undoped semiconductors, but the disclosure is not limited thereto.

The plurality of wires may include, for example, scan lines (not shown), data lines (not shown), voltage lines (not shown) and other suitable wires. The scan lines are, for example, coupled to the gates of the switching elements, and the scan lines may be, for example, used to provide scan signals to the corresponding switching elements to turn on the switching elements. The data lines are for example coupled to the source of the switching element, and the signal (carrier) generated by the photoelectric element may be transmitted to the data line via the source, and the data line may transmit the signal (carrier) to the processing circuit (not shown). The voltage line is, for example, coupled to the photoelectric element, and the voltage line may be used, for example, to apply a voltage level to the photoelectric element.

It is worth noting that, in some embodiments, before forming the circuit layer CL on the first surface FB1_S1 of the first flexible board FB1, the first flexible board FB1 may be disposed on the carrier board CB1. The second surface FB1_S2 of the first flexible board FB1 (opposite to the first surface FB1_S1) faces the carrier board CB1, the material of the carrier board CB1 may include a hard material, and the hard material may be, for example, glass. After the circuit layer CL is formed on the first surface FB1_S1 of the first flexible board FB1, the first flexible board FB1 may be separated from the carrier board CB1 by, for example, a laser lift off process (LLO), but this disclosure is not limited thereto.

Please continue to refer to FIG. 1 and FIG. 2. In step S20, a second flexible board FB2 is provided, and the first flexible board FB1 is fixed on the second flexible board FB2, and the first flexible board FB1 is disposed between the circuit layer CL and the second flexible board FB2.

The second flexible board FB2 may, for example, serve as a substrate for subsequently supporting the scintillator. Therefore, the thickness FB2_T of the second flexible board FB2 may be different from the thickness FB1_T of the first flexible board FB1. In this embodiment, the thickness FB1_T of the first flexible board FB1 is smaller than the thickness FB2_T of the second flexible board FB2, but the disclosure is not limited thereto. In some embodiments, the thickness FB2_T of the second flexible board FB2 may be between 10 microns and 400 microns, but the disclosure is not limited thereto. The material of the second flexible board FB2 may include polyimide (PI), polyethylene terephthalate (PET), polyethylene naphthalate (PEN) or other suitable materials or combinations of the above materials, the present disclosure is not limited thereto. The material of the second flexible board FB2 and the material of the first flexible board FB1 may, for example, be the same or similar, and the present disclosure is not limited thereto.

In some embodiments, the second flexible board FB2 may be fixed on the first flexible board FB1 by disposing an adhesive layer AL1 on the first flexible board FB1. In detail, for example, an adhesive layer AL1 may be provided on the second surface FB1_S2 of the first flexible board FB1 (or the first surface FB2_S1 of the second flexible board FB2), and then the second flexible board FB2 and the first flexible board FB1 may be bonded to each other through the adhesive layer AL1. The first surface FB2_S1 of the second flexible board FB2 faces the second surface FB1_S2 of the first flexible board FB1, so that the first flexible board FB1 is between the circuit layer CL and the second flexible board FB2. The material of the adhesive layer AL1 may be, for example, pressure sensitive adhesives (PSA), double-sided tape, thermosetting adhesive or other suitable adhesive layers, and the present disclosure is not limited thereto. In some embodiments, the thickness AL1_T of the adhesive layer AL1 may be between 10 microns and 200 microns, but the disclosure is not limited thereto.

Please continue to refer to FIG. 1 and FIG. 2. In step S30, the carrier board CB2 is provided, the carrier board CB2 is fixed on the second flexible board FB2, and the second flexible board FB2 is disposed between the carrier board CB2 and the first flexible board FB1.

The carrier board CB2 may, for example, be used to carry the above-mentioned first flexible board FB1, the second flexible board FB2 and circuit layer CL. The material of the carrier CB2 may, for example, include a hard material, and may be the same or similar to that of the carrier board CB1, and the present disclosure is not limited thereto.

In some embodiments, the carrier board CB2 may be fixed on the second flexible board FB2 by providing an adhesive layer AL2. In detail, for example, an adhesive layer AL2 may be provided on the second surface FB2_S2 of the second flexible board FB2 (or a surface of the carrier board CB2), and then the carrier board CB2 and the second flexible board FB2 are bonded through the adhesive layer AL2. The second surface FB2_S2 of the second flexible board FB2 faces the carrier board CB2, so that the second flexible board FB2 is disposed between the carrier board CB2 and the first flexible board FB1. The material of the adhesive layer AL2 and the material of the adhesive layer AL1 may, for example, be the same or similar, and the present disclosure is not limited thereto.

Please continue to refer to FIG. 1 and FIG. 2. In step S40, a scintillator SC is formed on the circuit layer CL. In this embodiment, the scintillator SC is formed on the circuit layer CL through direct deposition. In detail, for example, the surface of the circuit layer CL away from the first flexible board FB1 may face the evaporation source (not shown), and then the evaporation source may generate the evaporation source material (not shown) after being heated, and this evaporation source material may be deposited on the surface of the circuit layer CL away from the first flexible board FB1 to form the scintillator SC. The material of the scintillator SC includes, for example, a material that efficiently converts the energy of radiation such as X-rays incident from the outside into visible light. In this embodiment, the material of the scintillator SC includes cesium iodide (CsI).

Please continue to refer to FIG. 1 and FIG. 2. In step S50, a protective layer EL is formed on the scintillator SC. The protective layer EL, for example, covers the scintillator SC in the normal direction n of the first flexible board FB1, and includes, for example, alloy foil, metal foil, polyethylene terephthalate, polyethylene naphthalate, parylene and so on to reduce the possibility of deliquescence and/or oxidation of the scintillator SC caused by the external environment. In this embodiment, the protective layer EL has a cap-shaped structure, that is, the protective layer EL may also cover part of the first flexible board FB1 in addition to covering the scintillator SC, but the present disclosure is not limited thereto. In some embodiments, the thickness EL_T of the protective layer EL may be between 5 microns and 300 microns, but the disclosure is not limited thereto.

Please continue to refer to FIG. 1 and FIG. 2. In step S60, the carrier board CB2 is separated from the second flexible board FB2. In this embodiment, through the arrangement of the adhesive layer AL2, the second flexible board FB2 may be separated from the carrier board CB2 by using a mechanical peeling method. Based on this, this embodiment may reduce the possibility of defects in the scintillator SC due to the separation of the second flexible board FB2 from the carrier board CB2 by using the laser lift-off method. It should be noted that the adhesive layer AL2 may also be separated from the second flexible board FB2 by, for example, the above-mentioned mechanical peeling method.

Please continue to refer to FIG. 1 and FIG. 2. In step S70, the first flexible board FB1 and the second flexible board FB2 are cut to form the detection panel 10a. In some embodiments, the first surface FB1_S1 of the first flexible board FB1 may include a cutting line CUT, and the first flexible board FB1 and the second flexible board FB2 may be cut along the cutting line CUT by using a laser cutting process or a knife wheel cutting process, and the disclosure is not limited thereto. The edges of the layers in the detection panel 10a formed by this cutting process may be aligned with each other in the normal direction n of the first flexible board FB1. In detail, in this embodiment, the edge CL_E of the circuit layer CL, the edge FB1_E of the first flexible board FB1, the edge AL1_E of the adhesive layer AL1, and the edge FB2_E of the second flexible board FB2 may be aligned with each other in the normal direction n of the first flexible board FB1. From another point of view, the areas of the first flexible board FB1 and the second flexible board FB2 are, for example, equal to each other after cutting; or, in the top view of the detection panel 10a, the first flexible board FB1 is overlapped with the second flexible board FB2 after they are cut.

It is worth noting that in the above step S70, cutting the first flexible board FB1 and the second flexible board FB2 may remove the peripheral area (not shown) of the first flexible board FB1 together with the electrostatic protection circuit (not shown) electrically connected with the circuit layer CL, but the present disclosure is not limited thereto.

At this stage, the fabrication of the detection panel 10a of this embodiment is completed, but the disclosure is not limited thereto.

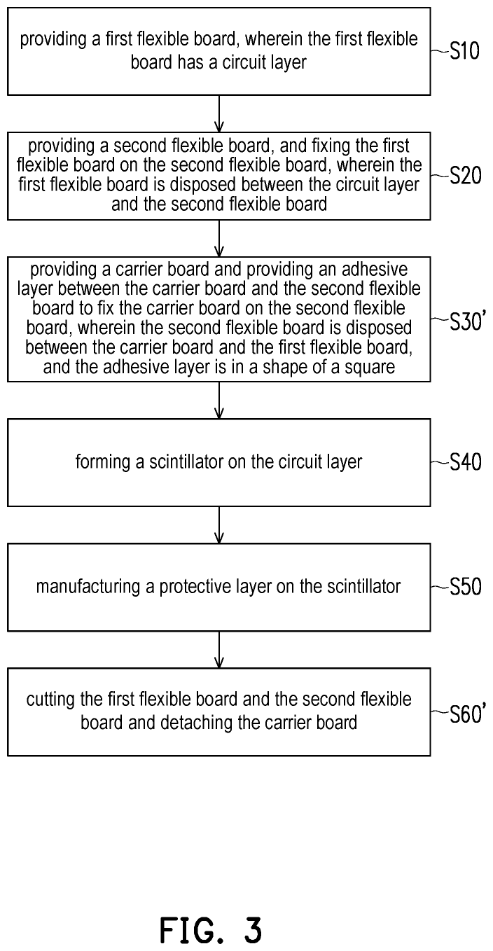

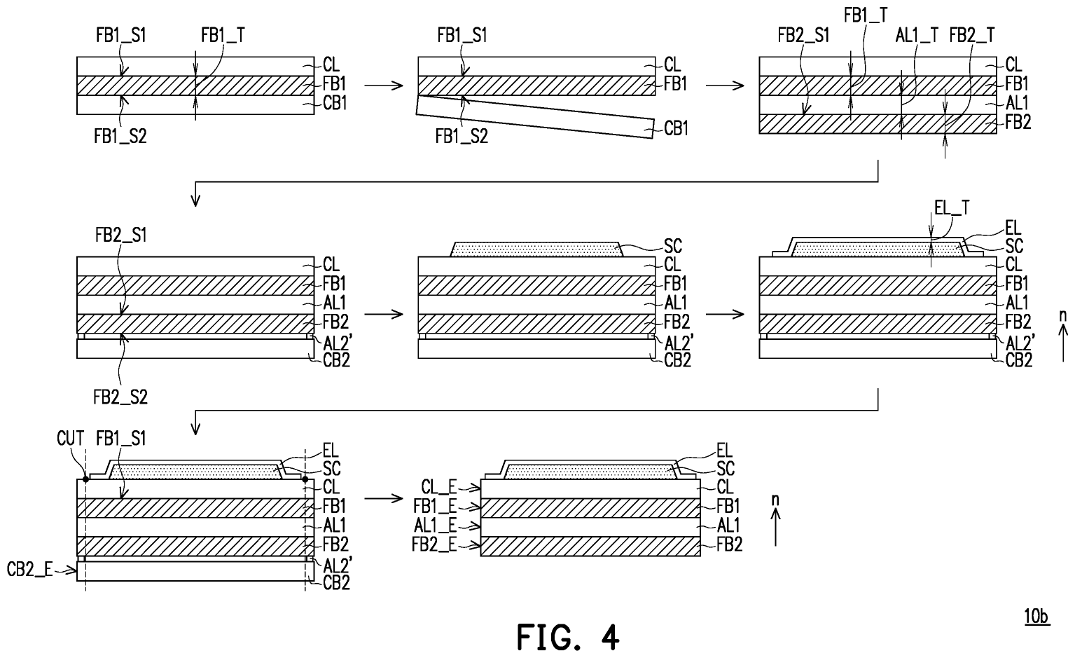

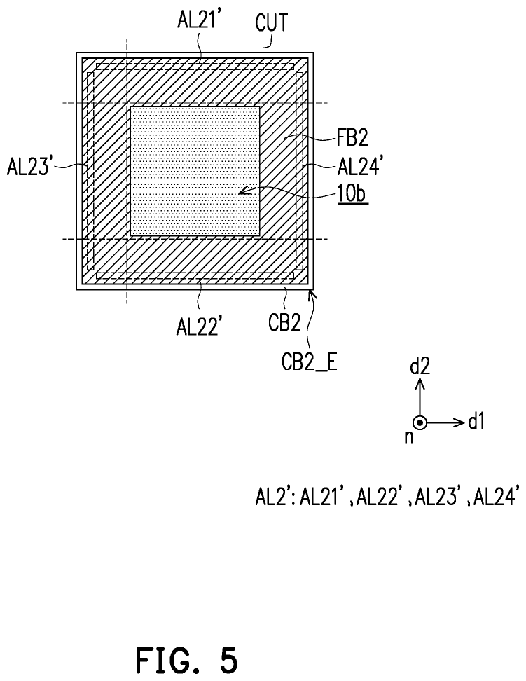

FIG. 3 is a flowchart of a method for manufacturing a detection panel according to another embodiment of the disclosure. FIG. 4 is a schematic cross-sectional flow diagram of a method of manufacturing a detection panel according to another embodiment of the present disclosure. FIG. 5 is a schematic top view before cutting the first flexible board and the second flexible board in the method of manufacturing the detection panel according to an embodiment of the present disclosure. It should be noted that, the embodiments of FIG. 3 to FIG. 5 can adopt the component numbers and parts of the embodiment of FIG. 1 and/or FIG. 2, and the same or similar symbols are used to represent the same or similar components, and the same technical descriptions are omitted.

Please refer to FIG. 3 to FIG. 5 at the same time. The main difference between the manufacturing method of the detection panel 10b shown in FIG. 3 to FIG. 5 and the manufacturing method of the detection panel 10a described above is that step S30′ is performed instead of step S30, and which provides a square-shaped adhesive layer AL2′ between the carrier board CB2 and the second flexible board FB2.

In detail, in step S30′ of this embodiment, a carrier board CB2 is provided and an adhesive layer AL2′ is provided between the carrier board CB2 and the second flexible board FB2, so as to fix the carrier board CB2 on the second flexible board FB2. The second flexible board FB2 is disposed between the carrier board CB2 and the first flexible board FB1, and the adhesive layer AL2′ is in the shape of a square in the top view of the detection panel 10b.

Please refer to FIG. 5, in this embodiment, the adhesive layer AL2′ is not completely formed on the carrier board CB2, but presents a square shape in the normal direction n of the first flexible board FB1. In some embodiments, the adhesive layer AL2′ may include adhesive patterns AL21′ and AL22′ extending along the first direction d1 as well as the adhesive patterns AL23′ and AL24′ extending along the second direction d2. The first direction d1 may be perpendicular to the second direction d2, and the first direction d1 and the second direction d2 may be perpendicular to the normal direction n of the first flexible board FB1. The two ends of the adhesive pattern AL21′, the adhesive pattern AL22′, the adhesive pattern AL23′ and the adhesive pattern AL24′ May or may not be in contact with the two ends of the other corresponding adhesive patterns, and the present disclosure is not limited thereto.

Based on this, by performing the above step S30′, the step S60 and the step S70 in the foregoing embodiment may be combined into a step S60′.

In detail, please refer to FIG. 3 to FIG. 5 at the same time. After step S50, step S60′ is performed to cut the first flexible board FB1 and the second flexible board FB2 and separate the carrier board CB2. In this embodiment, the first flexible board FB1 and the second flexible board FB2 are cut along the cutting line CUT on the first surface FB1_S1 of the first flexible board FB1, and the cutting line CUT is farther away from the edge CB2_E of the carrier board CB2 than the adhesive layer AL2. Based on this, after cutting the first flexible board FB1 and the second flexible board FB2, there is no adhesive layer AL2′ between the cut second flexible board FB2 and the carrier board CB2, and the second flexible board FB2 may be automatically separated from carrier board CB2.

To sum up, in the method of manufacturing detection panel provided by some embodiments of the present disclosure, the scintillator is directly formed on the circuit layer, that is, the scintillator is formed on the circuit layer by performing a direct evaporation process, so that the possibility of generating air bubbles between the scintillator and the circuit layer may be reduced, and the number of layers between the scintillator and the circuit layer may also be decreased, so the quantum efficiency and/or resolution of the detection panel of some embodiments of the present disclosure may be improved.

In addition, in the method of manufacturing detection panel provided by other embodiments of the present disclosure, the first flexible board and the second flexible board are provided as the support boards of the detection panel, which may have the characteristics of light weight and withstanding the impact of a fall while having a certain level of strength, thus improving the quality of the detection panels in other embodiments of the present disclosure.

Moreover, in the method of manufacturing the detection panel provided in some embodiments of the present disclosure, an adhesive layer is provided between the carrier board and the second flexible board, so the second flexible board and the carrier board may be separated by a mechanical peeling method. Based on this, in the method of manufacturing the detection panel provided by some other embodiments of the present disclosure, the possibility of generating defects in the scintillator formed on the first flexible board due to the laser lift off method used to separate the second flexible board from the carrier board may be reduced.

The above embodiments are only used to illustrate the technical solutions of the present disclosure, rather than to limit them; although the present disclosure has been described in detail with reference to the foregoing embodiments, those of ordinary skill in the art should understand that: they may still make modification to the technical solutions described in the foregoing embodiments, or some or all of the technical features may be replaced equivalently; and these modifications or replacements do not make the essence of the corresponding technical solutions depart from the scope of the technical solutions of the embodiments disclosed in this disclosure.

What is claimed is:

1. A method for manufacturing a detection panel, comprising:
providing a first flexible board, wherein the first flexible board has a circuit layer;
providing a second flexible board, and fixing the first flexible board on the second flexible board, wherein the first flexible board is disposed between the circuit layer and the second flexible board;
providing a carrier board, and fixing the carrier board on the second flexible board, wherein the second flexible board is disposed between the carrier board and the first flexible board;
forming a scintillator on the circuit layer;
detaching the carrier board from the second flexible board; and
cutting the first flexible board and the second flexible board to form the detection panel.

2. The method for manufacturing the detection panel according to claim 1, further comprising manufacturing a protective layer on the scintillator before detaching the carrier board.

3. The method for manufacturing the detection panel according to claim 2, wherein the protective layer has a cap-like structure.

4. The method for manufacturing the detection panel according to claim 1, wherein a thickness of the first flexible board is different from a thickness of the second flexible board.

5. The method for manufacturing the detection panel according to claim 4, wherein the thickness of the first flexible board is smaller than the thickness of the second flexible board.

6. The method for manufacturing the detection panel according to claim 1, wherein areas of the first flexible board and the second flexible board are equal to each other after cutting.

7. The method for manufacturing the detection panel according to claim 1, wherein in a top view of the detection panel, the first flexible board is overlapped with the second flexible board after the first flexible board and the second flexible board are cut.

8. The method for manufacturing the detection panel according to claim 1, wherein the scintillator is formed on the circuit layer through direct vapor deposition.

9. The method for manufacturing the detection panel according to claim 1, wherein a mechanical peeling method is utilized to detach the carrier board from the second flexible board.

10. A method for manufacturing a detection panel, comprising:
providing a first flexible board, wherein the first flexible board has a circuit layer;
providing a second flexible board, and fixing the first flexible board on the second flexible board, wherein the first flexible board is disposed between the circuit layer and the second flexible board;
providing a carrier board, and fixing the carrier board on the second flexible board, wherein the second flexible board is disposed between the carrier board and the first flexible board;
forming a scintillator on the circuit layer; and
cutting the first flexible board and the second flexible board and detaching the carrier board.

11. The method for manufacturing the detection panel according to claim 10, further comprising manufacturing a protective layer on the scintillator before detaching the carrier board.

12. The method for manufacturing the detection panel according to claim 11, wherein the protective layer has a cap-like structure.

13. The method for manufacturing the detection panel according to claim 10, wherein a thickness of the first flexible board is different from a thickness of the second flexible board.

14. The method for manufacturing the detection panel according to claim 13, wherein the thickness of the first flexible board is smaller than the thickness of the second flexible board.

15. The method for manufacturing the detection panel according to claim 10, wherein areas of the first flexible board and the second flexible board are equal to each other after cutting.

16. The method for manufacturing the detection panel according to claim 10, wherein in a top view of the detection panel, the first flexible board is overlapped with the second flexible board after the first flexible board and the second flexible board are cut.

17. The method for manufacturing the detection panel according to claim 10, further comprising providing an adhesive layer between the carrier board and the second flexible board.

18. The method for manufacturing the detection panel according to claim 17, wherein the adhesive layer is in a shape of a square in a top view of the detection panel.

19. The method for manufacturing the detection panel according to claim 18, wherein cutting the first flexible board and the second flexible board is performed along a cutting line, wherein the cutting line is farther away from an edge of the carrier board than the adhesive layer.

20. The method for manufacturing the detection panel according to claim 10, wherein the scintillator is formed on the circuit layer through direct vapor deposition.
